(19) United States
(12) Patent Application Publication
(10) Pub. No.: US 2026/0156862 A1
(43) Pub. Date: Jun. 4, 2026

(54) SEMICONDUCTOR STRUCTURE AND BULK CONVERTER

(71) Applicant: MEDIATEK INC., Hsinchu City (TW)

(72) Inventors: Je-Min WEN, Hsinchu City (TW); Yan-Liang JI, Hsinchu City (TW); Bo-Yu WEI, Hsinchu City (TW)

(21) Appl. No.: 19/391,031

(22) Filed: Nov. 17, 2025

Related U.S. Application Data
(60) Provisional application No. 63/726,681, filed on Dec. 2, 2024.

(51) Int. Cl. H10D 30/65; H02M 3/158; H10D 62/10

(52) U.S. Cl. CPC H10D 30/655; H02M 3/158; H10D 62/107; H10D 62/116

(57) ABSTRACT

A semiconductor structure and a buck convertor are provided. The semiconductor structure includes a substrate, a body region, a drift region, a first deep well region, a gate structure, a source region and a drain region. The body region and the adjacent drift region are located in the substrate. The body region has a first conductivity type. The drift region has a second conductivity type that is different from the first conductivity type. The first deep well region is located below the body region and the drift region and has the first conductivity type. The gate structure is located on the drift region and adjacent to the body region. The source region is located on the body region. The drain region is located adjacent to the drift region in contact with the first deep well region. The source and drain regions have the second conductivity type.

### CROSS REFERENCE TO RELATED APPLICATIONS

This Application claims the benefit of U.S. Provisional Application No. 63/726,681, filed on Dec. 2, 2024, the entirety of which is incorporated by reference herein.

### TECHNICAL FIELD

The present disclosure relates to a semiconductor structure and a bulk convertor, and, in particular, it relates to a semiconductor structure and a bulk convertor having a controlled breakdown path.

### BACKGROUND

Recently, as demand has increased for high-voltage devices such as power semiconductor devices, there has been an increasing interest in research on high-voltage metal-oxide-semiconductor field effect transistors (HV MOSFETs) applied in high-voltage devices.

Among the various types of high-voltage metal-oxide-semiconductor field effect transistors (HV MOSFETs), semiconductor devices such as lateral double diffused metal-oxide-semiconductor (LDMOS) devices are often used.

However, with progress being made in semiconductor fabrication, the breakdown voltage of high-voltage MOSFETs for high-voltage devices needs to be carefully controlled so as not to exceed the operating voltage. Thus, a reliable high-voltage MOSFET for high-voltage devices having a controlled breakdown path is needed to meet device performance requirements as the continuous needs of semiconductor fabrication of high-voltage devices.

### BRIEF SUMMARY

An embodiment of the present disclosure provides a semiconductor structure. The semiconductor structure includes a substrate, a body region, a drift region, a first deep well region, a gate structure, a source region and a drain region. The body region is located in the substrate. The body region has a first conductivity type. The drift region is located in the substrate and adjacent to the body region. The drift region has a second conductivity type that is different from the first conductivity type. The first deep well region is located in the substrate and below the body region and the drift region. The first deep well region has the first conductivity type. The gate structure is located on the drift region and adjacent to the body region. The source region is located on the body region. The source region has the second conductivity type. The drain region is located adjacent to the drift region in contact with the first deep well region. The drain region has the second conductivity type.

An embodiment of the present disclosure provides a bulk convertor. The bulk convertor includes a buck controller, a low voltage (LS) device, and a high voltage (HS) device. The low voltage (LS) device is connected to the buck controller. The high voltage (HS) device is connected to the buck controller. The high voltage (HS) device is composed of a first semiconductor structure including a substrate, a body region, a drift region, a first deep well region, a gate structure, a source region and a drain region. The body region is located on the first deep well region. The body region has a first conductivity type. The drift region is located on the first deep well region and adjacent to the body region. The drift region has a second conductivity type that is different from the first conductivity type. The first deep well region is located in the substrate and below the body region and the drift region. The first deep well region has the first conductivity type. The gate structure is located on the drift region and adjacent to the body region. The source region is located on the body region. The source region has the second conductivity type. The drain region is located adjacent to the drift region in contact with the first deep well region. The drain region has the second conductivity type.

In some embodiments, the low voltage (LS) device is composed of a second semiconductor structure that is the same as the first semiconductor structure.

### BRIEF DESCRIPTION OF THE DRAWINGS

The present disclosure can be more fully understood by reading the subsequent detailed description and examples with references made to the accompanying drawings, wherein:

FIG. 1 is a schematic top view of a semiconductor structure in accordance with some embodiments of the disclosure;

FIG. 2 is a schematic cross-sectional view of the semiconductor structure along the line A-A′ of FIG. 1 in accordance with some embodiments of the disclosure;

FIG. 3 is a schematic cross-sectional view of the semiconductor structure along the line A-A′ of FIG. 1 in accordance with some embodiments of the disclosure; and

FIG. 4 is a circuit diagram of a buck device including the semiconductor structures of FIGS. 1, 2 and 3 in accordance with some embodiments of the present disclosure.

### DETAILED DESCRIPTION

The following description is made for the purpose of illustrating the general principles of the disclosure and should not be taken in a limiting sense. The scope of the disclosure is best determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

High-voltage metal-oxide-semiconductor field effect transistors (HV MOSFETs), such as power MOSFETs have been used as switching devices of a buck converter. In the conventional buck converter, however, the buck power stage metal-oxide-semiconductor field-effect transistor (MOSFET) (consists of a high voltage side (HS) MOSFET and a low voltage side (LS) MOSFET in a half-bridge configuration) may suffer damage during operation when input voltage (Vin) bouncing happed and out of device safe operating area (SOA) due to the undesired breakdown path of the MOSFET. Thus, a reliable high-voltage MOSFET for high-voltage devices having a controlled breakdown path is needed to meet device performance requirements as the needs of semiconductor fabrication of high-voltage devices continue.

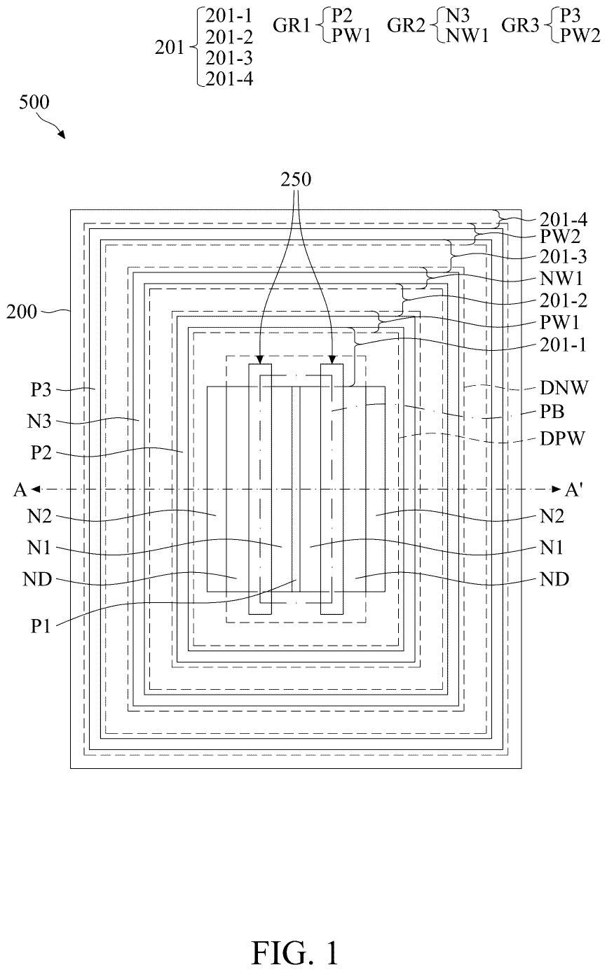

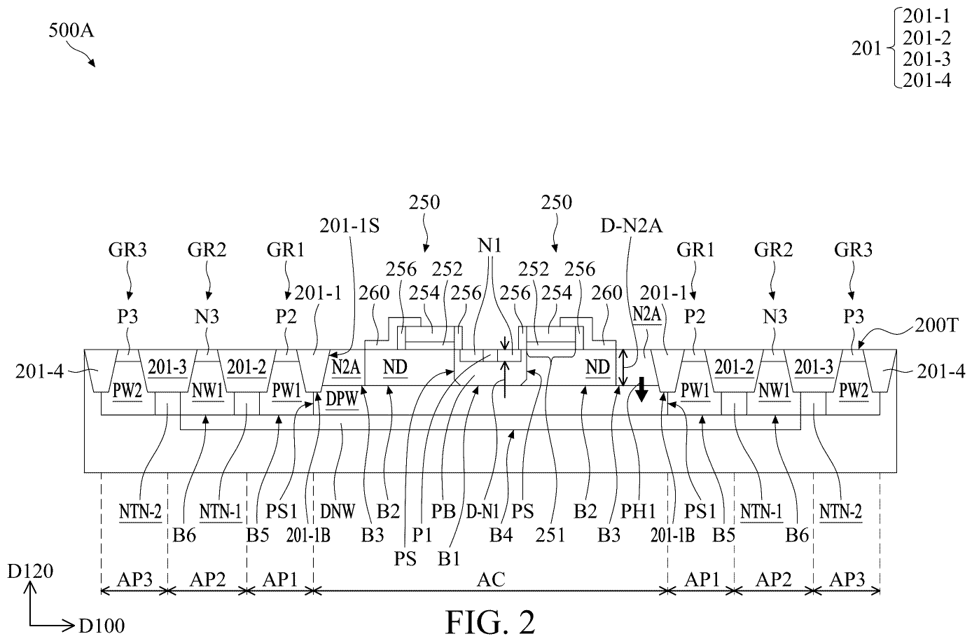

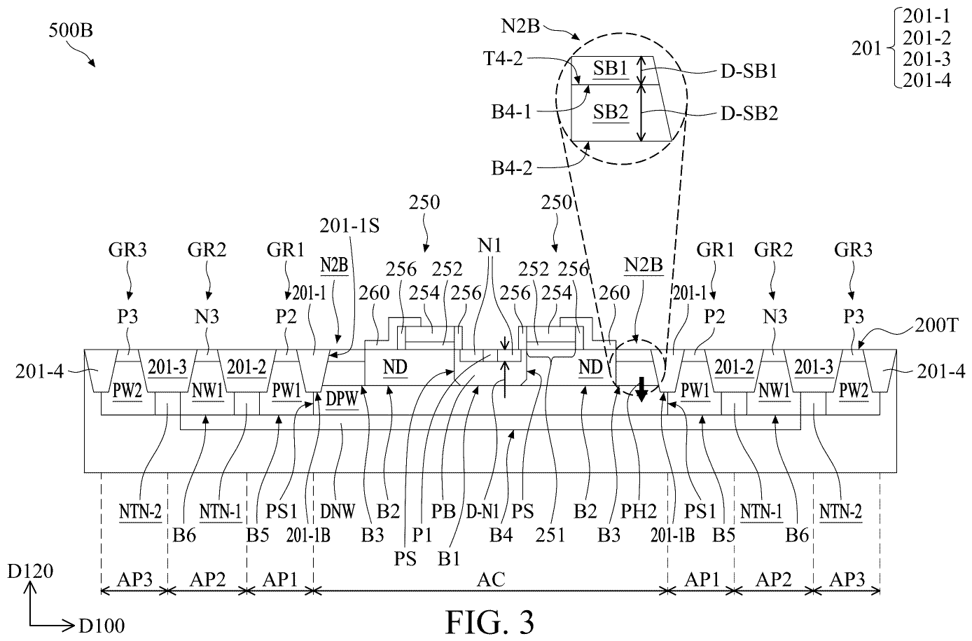

FIG. 1 is a schematic top view of a semiconductor structure 500 (including semiconductor structures 500A and 500B shown in FIGS. 2 and 3) in accordance with some embodiments of the disclosure. FIG. 2 is a schematic cross-sectional view of the semiconductor structure 500A along the line A-A′ of FIG. 1 in accordance with some embodiments of the disclosure. In some embodiments, the semiconductor structure 500A includes a transistor such as a lateral diffused MOS (LDMOS) transistor, and the transistor includes a substrate 200, a body region PB, a drift region ND, a first deep well region DPW, a gate structure 250, a source region N1 and a drain region N2A (a drain region N2 of FIG. 1 includes drain regions N2A and N2B shown in FIGS. 2 and 3). In FIG. 2 and the following cross-sectional views, direction D100 is defined as lateral directions that is parallel to a top surface 200T of the substrate 200, and direction D120 is defined as a vertical direction that is vertical to the top surface 200T of the substrate 200.

In some embodiments, the substrate 200 includes a central active region AC surrounded by peripheral active regions AP1, AP2, and AP3. The central active region AC and the peripheral active regions AP1, AP2, and AP3 are defined by isolation features 201 (including isolation features 201-1, 201-2, 201-3, and 201-4) such as shallow trench isolation trench isolations (STIs). For example, the central active region AC is defined by the isolation feature 201-1. The peripheral active region AP1 surrounding the central active region AC is defined by the isolation features 201-1 and 201-2. The peripheral active region AP2 surrounding the peripheral active region AP1 is defined by the isolation features 201-2 and 201-3. The peripheral active region AP3 surrounding the peripheral active region AP2 is defined by the isolation features 201-3 and 201-4. The body region PB, the drift region ND, the first deep well region DPW, the gate structure 250, the source region N1 and the drain region N2A are formed in the central active region AC. The semiconductor structure 500A is substantially symmetrical with respect with the body region PB.

In some embodiments, the isolation feature 201 includes silicon oxide, silicon nitride, silicon oxynitride (SiON), another suitable insulating material, or a combination thereof. In some embodiments, the isolation features 201 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

The substrate 200 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP. The substrate 200 may be doped with dopants having a conductivity type that is either P-type or N-type. In some embodiments, the substrate 200 is P-type.

The body region PB and the drift region ND are located in the substrate 200. The body region PB and the drift region ND may be adjacent to each other. In some embodiments, the drift region ND surrounds and is in contact with opposite sidewalls PS of the body region PB. Therefore, the sidewalls PS of the body region PB may also serve as interfaces PS between the body region PB and the drift region ND. In some embodiments, the body region PB has a first conductivity type. For example, when the first conductivity type is P-type, the body region PB is a P-type body region PB. In some embodiments, the drift region ND has a second conductivity type that is different from the first conductivity type. For example, when the first conductivity type is P-type, the second conductivity type is N-type, and the drift region ND is an N-type drift region ND.

The first deep well region DPW is located in the substrate 200. In addition, the first deep well region DPW is below the body region PB and the drift region ND. Furthermore, bottom B1 of the body region PB and a bottom B2 of the drift region ND are in contact with different portions of the first deep well region DPW. In some embodiments, an interface between the body region PB and the first deep well region DPW (i.e., the bottom B1 of the body region PB) is substantially level with an interface between the drift region ND and the first deep well region DPW (i.e., the bottom B2 of the drift region ND). As shown in FIG. 2, the interfaces PS between the body region PB and the drift region ND are directly above the first deep well region DPW.

As shown in FIG. 2, a bottom 201-1B of the isolation feature 201-1 surrounding the body region PB and the drift region ND is located below the interface between the body region PB and the first deep well region DPW (i.e., the bottom B1 of the body region PB) and the interface between the drift region ND and the first deep well region DPW (i.e., the bottom B2 of the drift region ND).

In some embodiments, the first deep well region DPW has the first conductivity type. For example, when the first conductivity type is P-type, the first deep well region DPW is a P-type deep well region DPW.

The gate structure 250 is formed on the substrate 200. In addition, the gate structure 250 is located on the drift region ND and adjacent to the body region PD. In some embodiments, the gate structure 250 includes a gate dielectric layer 252 and a gate electrode layer 254 formed on the gate dielectric layer 252. A pair of gate spacer layers 256 are formed on opposite sidewall surfaces of the gate structure 250. The gate electrode layer 254 is separated from the drift region ND by the gate dielectric layer 252. A channel region 251 is directly below the gate structure 250 and between the source region N1 and the drain region N2A.

In some embodiments, the dielectric constant of the gate dielectric layer 252 is greater than the dielectric constant of the gate spacer layer 256. In some embodiments, the gate dielectric layers 252 includes one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layer 252 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In some embodiments, the gate spacer layers 256 includes a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the gate spacer layer 256 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In some embodiments, the gate electrode layer 254 includes one or more layers of conductive material, such as aluminum, copper, titanium, tantalum, tungsten, cobalt, molybdenum, tantalum nitride, nickel silicide, cobalt silicide, TiN, WN, TiAl, TiAIN, TaCN, TaC, TaSiN, metal alloys, another suitable material, or a combination thereof. In some embodiments, the gate electrode layer 254 is formed using chemical vapor deposition (CVD), atomic layer deposition (ALD), electroplating, another applicable method, or a combination thereof.

Other conductive layers, such as work function metal layers, may also be formed in the gate structure 250, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAIN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

The source region NI is located on the body region PB and close to the gate structure 250. In some embodiments, the source region N1 has the second conductivity type. For example, when the first conductivity type is P-type, the second conductivity type is N-type, and the source region N1 is an N-type source region N1. In addition, the semiconductor structure 500A may further include a pick-up region P1 is formed on the body region PB and adjacent to the source region N1. The pick-up region P1 is in direct contact with the source region N1. In some embodiments, the pick-up region P1 has the first conductive type. For example, when the first conductivity type is P-type, the pick-up region P1 is a P-type pick-up region P1 In some embodiments, the doping concentration of the pick-up region P1 is greater than the doping concentration of the body region PB. In some embodiments, the doping concentration of the body region PB is in a range from about 10¹³/cm² to about 10¹⁴/cm², and the doping concentration of the pick-up region P1 is in a range from 10¹⁴/cm² to about 10¹⁵/cm².

The drain region N2A is located adjacent to the drift region ND and opposite the body region PB. Opposite sidewalls of the drain region N2A are in contact with the drift region ND and the isolation feature 201-1 surrounding the drift region ND, the body region PB and the drain region N2A. A bottom B3 of the drain region N2A is in contact with the first deep well region DPW. In some embodiments, the bottom B3 of the drain region N2A, the bottom B1 of the body region PB and a bottom B2 of the drift region ND are in contact with different portions of the first deep well region DPW. In some embodiments, an interface between the drain region N2A and the first deep well region DPW (i.e., the bottom B3 of the drain region N2A) is level with the interface between the body region PB and the first deep well region DPW (i.e., the bottom B1 of the body region PB) and the interface between the drift region ND and the first deep well region DPW (i.e., the bottom B2 of the drift region ND).

In some embodiments, a depth D-N2A of the drain region N2A is greater than a depth D-N1 of the source region N1. In some embodiments, the depth D-N2A of the drain region N2A may be the same as the depths of the body region PB and the drift region ND.

As shown in FIGS. 1 and 2, the bottom 201-1B of the isolation feature 201-1 surrounding the drain region N2A is located below the interface between the drain region N2A and the first deep well region DPW (i.e., the bottom B3 of the drain region N2A). In addition, a side surface 201-1S of the isolation feature 201-1 is adjacent to the first deep well region DPW and the drain region N2A.

In some embodiments, the drain region N2A has the second conductivity type. For example, when the first conductivity type is P-type, the second conductivity type is N-type, and the drain region N2A is an N-type drain region N2A.

In some embodiments, the doping concentration of the drain region N2A is greater than the doping concentration of the drift region ND. In some embodiments, the doping concentration of the drift region ND is in a range about 3*101²/cm² to about 6*10¹²/cm², and the doping concentration of the drain region N2A is in a range from 10¹⁴/cm² to about 10¹⁵/cm².

In some embodiments, the doping concentration of the drain region N2A is greater than or equal to the doping concentration of the source region N1.

The semiconductor structure 500A may further include a silicide block layer 260 is formed on a portion of the gate structure 250 and a portion of the gate spacer layer 256 and on the substrate 200. More specifically, the silicide block layer 260 covers the top surface of the gate electrode layer 254 of the gate structure 250 and the sidewall surface of the gate spacer layer 256. In some embodiments, the silicide block layer 260 is configured to block the deposition of the silicide layers.

In some embodiments, the silicide block layer 260 includes oxide or nitride, such as silicon dioxide, silicon oxynitride, silicon nitride, or another applicable material. In some embodiments, the silicide block layer 260 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

As shown in FIGS. 1 and 2, the semiconductor structure 500A may further include guard rings GR1, GR2, and GR3 located in the peripheral active regions AP1, AP2, and AP 3 in the substrate 200, respectively. The body region PB, the drift region ND, the first deep well region DPW, the gate structure 250, the source region N1 and the drain region N2A are surrounded by the guard ring GR1. The guard ring GR1 is surrounded by the guard ring GR2. In addition, the guard ring GR2 is surrounded by the guard ring GR3. It is noted that the number of guard rings is not limited to the disclosed embodiments.

In some embodiments, the guard ring GR1 includes a well region PW1 and a pick-up region P2. The well region PW1 is located adjacent to the first deep well region DPW. In some embodiments, the interface between the drain region N2A and the first deep well region DPW (i.e., the bottom B3 of the drain region N2A) is located above the bottom 201-1B of the isolation feature 201-1. Therefore, the well region PW1 is separated from the drain region N2A by the isolation feature 201-1 and the first deep well region DPW. The pick-up region P2 is located on the well region PW. In addition, the pick-up region P2 is separated from the drain region N2A by the isolation feature 201-1.

In some embodiments, the well region PW1 and the pick-up region P2 both have the first conductivity type. For example, when the first conductivity type is P-type, the well region PW1 is a P-type well region PW1, and the pick-up region P2 is a P-type pick-up region P2. In some embodiments, the doping concentration of the pick-up region P2 is greater than the doping concentration of the well region PW1. In some embodiments, the doping concentration of body region PB is greater than doping concentration of the well region PW1. In some embodiments, the doping concentration of the pick-up region P1 is equal to the doping concentration of the pick-up region P2. In some embodiments, the doping concentration of the pick-up region P2 is in a range from 10¹⁴/cm² to about 10¹⁵/cm². In some embodiments, the doping concentration of the well region PW1 is in a range about 1*10¹²/cm² to about 2*10¹²/cm².

In some embodiments, the guard ring GR2 includes a well region NW1 and a pick-up region N3. The well region NW1 may surround the well region PW1. The well region NW1 is separated from the well region PW1. The pick-up region N3 is located on the well region NW. In addition, the pick-up region N3 is separated from the drain region N2A by the isolation feature 201-2.

In some embodiments, the well region NW1 and the pick-up region N3 both have the second conductivity type. For example, when the first conductivity type is P-type, the second conductivity type is N-type, the well region NW1 is an N-type well region NW1, and the pick-up region N3 is an N-type pick-up region N3. In some embodiments, the doping concentration of the pick-up region N3 is greater than the doping concentration of the well region NW1. In some embodiments, the doping concentration of drift region ND is greater than doping concentration of the well region NW1. In some embodiments, the doping concentration of the source region N1 is equal to the doping concentration of the pick-up region N3. In some embodiments, the doping concentration of the pick-up region N3 is in a range from 10¹⁴/cm² to about 10¹⁵/cm². In some embodiments, the doping concentration of the well region NW1 is in a range about 1*10¹²/cm² to about 2*10¹²/cm².

As shown in FIG. 2, the semiconductor structure 500A may further include a second deep well region DNW. The second deep well region DNW is located in the substrate 200 and below the first deep well region DPW and the guard rings GR1 and GR2. The second deep well region DNW is configured to connect the well region NW1 of the guard ring GR2.

In some embodiments, a bottom B4 of the first deep well region DPW, a bottom B5 of the well region PW1 of the guard ring GR1 and a bottom B6 of the well region NW1 of the guard ring GR2 are in contact with different portions of the second deep well region DNW. In some embodiments, an interface between the first deep well region DPW and the second deep well region DNW (i.e., the bottom B4 of the first deep well region DPW) is substantially level with an interface between the well region PW1 and the second deep well region DNW (i.e., the bottom B5 of the well region PW1) and an interface between the well region NW1 and the second deep well region DNW (i.e., the bottom B6 of the well region NW1). As shown in FIG. 2, interfaces PS1 between the first deep well region DPW and the well region PW1 are directly above the second deep well region DNW.

In some embodiments, the second deep well region DNW has the second conductivity type. For example, when the first conductivity type is P-type, the second conductivity type is N-type, the second deep well region DNW is an N-type deep well region DNW.

As shown in FIG. 2, the semiconductor structure 500A may further include an intrinsic doped region NTN-1. The intrinsic doped region NTN-1 is a region of the substrate 200 surrounded by the guard rings GR1, GR2, the isolation feature 201-2 and the second deep well region DNW. The upper portion of the well region NW1 is separated from the upper portion of the well region PW1 by the isolation feature 201-2. In addition, the lower portion of the well region NW1 is separated from the lower portion of the well region PW1 by the intrinsic doped region NTN-1. In some embodiments, the intrinsic doped region NTN-1 and the substrate 200 have the same conductivity type and doping concentration.

In some embodiments, the well region PW1 of the guard ring GR1, the intrinsic doped region NTN-1 and the well region NW1 of the guard ring GR2 may collectively form a parasitic P-i-N diode having a reduced junction capacitance (i.e., the depletion capacitance) and an increased junction resistance and a high breakdown voltage due to the larger depletion region at the P-type intrinsic doped region NTN-1.

In some embodiments, the guard ring GR3 includes a well region PW2 and a pick-up region P3. The well region PW2 is located adjacent to the first deep well region DPW. In addition, the well region PW2 is separated from the well region NW1. The pick-up region P3 is located on the well region PW2. In addition, the pick-up region P3 is separated from the pick-up region N3 by the isolation feature 201-3 surrounding the guard ring GR2.

In some embodiments, the well region PW2 and the pick-up region P3 both have the first conductivity type. For example, when the first conductivity type is P-type, the well region PW2 is a P-type well region PW2, and the pick-up region P3 is a P-type pick-up region P3. In some embodiments, the doping concentration of the pick-up region P3 is greater than the doping concentration of the well region PW2. In some embodiments, the doping concentration of body region PB is greater than doping concentration of the well region PW2. In some embodiments, the doping concentration of the pick-up region P1 is equal to the doping concentration of the pick-up region P3.

In some embodiments, the doping concentration of the well region PW1 is equal to the doping concentration of the well region PW2. The doping concentration of the pick-up region P2 is equal to the doping concentration of the pick-up region P3.

In some embodiments, the doping concentration of the pick-up region P3 is in a range from 10¹⁴/cm² to about 10¹⁵/cm². In some embodiments, the doping concentration of the well region PW2 is in a range about 1*10¹²/cm² to about 2*10¹²/cm².

In some embodiments, the guard rings GR1, GR2 and GR3 may be connected to a ground (GND) terminal (not shown).

As shown in FIG. 2, a region of the substrate 200 between the well region NW1 of the guard ring GR2 and the well region PW2 of the guard ring GR3 may also serve as an intrinsic doped region NTN-2. In other words, the upper portion of the well region NW1 is separated from the upper portion of the well region PW2 by the isolation feature 201-3. In addition, the lower portion of the well region NW1 is separated from the lower portion of the well region PW2 by the intrinsic doped region NTN-2. Since the intrinsic doped region NTN-2 is a region of the substrate 200, the intrinsic doped region NTN-2 and the substrate 200 have the same conductivity type and doping concentration.

In some embodiments, the well region NW1 of the guard ring GR2, the intrinsic doped region NTN-2 and the well region PW2 of the guard ring GR3 may collectively form a parasitic P-i-N diode having a reduced junction capacitance (i.e., the depletion capacitance) and an increased junction resistance and a high breakdown voltage due to the larger depletion region at the P-type intrinsic doped region NTN-2.

In the semiconductor structure 500A, the drain region N2A having the second conductivity type may extend down to the first deep well region DPW having the first conductivity type to form a PN junction. In addition, the drain region N2A has a higher doping concentration than drift region ND having the second conductivity type. The PN junction between the drain region N2A and the first deep well region DPW may have a lower breakdown voltage than the PN junction between the drift region ND and the first deep well region DPW. When the semiconductor structure 500A is operated at a high voltage, the PN junction between the drain region N2A and the first deep well region DPW is more susceptible to breakdown to form a current path (breakdown path) PH1 through the drain region N2A and the first deep well region DPW, and to the guard ring GR1 to discharge high current away from the gate dielectric layer 252. Therefore, the gate structure 250 of the transistor in the central active region AC is protected by the design of the drain region N2A. The gate dielectric layer 252 of the transistor in the central active region AC can be prevented form damage when the semiconductor structure 500A is operated at a high voltage.

FIG. 3 is a schematic cross-sectional view of a semiconductor structure 500B along the line A-A′ of FIG. 1 in accordance with some embodiments of the disclosure. Elements of the embodiments that are the same or similar to those previously described with reference to FIGS. 1 and 2 are not repeated herein, in the interests of brevity. As shown in FIGS. 1 to 2, the difference between the semiconductor structure 500A and the semiconductor structure 500B at least includes that the semiconductor structure 500B includes a drain region N2B including a plurality of sub-portions SB1 and SB2. It is noted that the number of sub-portions of the drain region N2B is not limited to the disclosed embodiments.

As shown in FIG. 3, the sub-portions SB1 and SB2 are arranged side by side in the direction D120 (also called the vertical direction) that is vertical to the top surface 200T of the substrate 200. The sub-portion SB1 may be in contact with the sub-portion SB2. More specifically, a bottom B4-1 of the sub-portion SB1 may be in contact with a top T4-2 the sub-portion SB2. In addition, a bottom B4-2 of the sub-portion SB2 may be in contact with the first deep well region DPW.

The sub-portions SB1 and SB2 of the drain region N2B is located adjacent to the drift region ND and opposite the body region PB. Opposite sidewalls of each of the sub-portions SB1 and SB2 are in contact with the drift region ND and the isolation feature 201-1 surrounding the drift region ND, the body region PB and the drain region N2B. In some embodiments, the bottom B4-2 of the sub-portion SB2, the bottom B1 of the body region PB and a bottom B2 of the drift region ND are in contact with different portions of the first deep well region DPW. In some embodiments, an interface between the drain region N2B and the first deep well region DPW (i.e., the B4-2 of the sub-portion SB2) is level with the interface between the body region PB and the first deep well region DPW (i.e., the bottom B1 of the body region PB) and the interface between the drift region ND and the first deep well region DPW (i.e., the bottom B2 of the drift region ND).

In the direction D120, a depth D-SB1 of the sub-portions SB1 may be the same or different a depth D-SB2 of the sub-portions SB2 according to the design of device electrical performances (e.g., breakdown voltage). In some embodiments, the depth of the drain region N2B (i.e., the total of the depths D-SB1 and D-SB2) is greater than the depth D-N1 of the source region N1. In some embodiments, the depth D-N2B of the drain region N2B may be the same as the depth of the body region PB and the depth of the drift region ND.

As shown in FIGS. 1 and 3, the bottom 201-1B of the isolation feature 201-1 surrounding the drain region N2B is located below the interface between the drain region N2B and the first deep well region DPW (i.e., the bottom B4-2 of the drain region N2B). In addition, the side surface 201-1S of the isolation feature 201-1 is adjacent to the first deep well region DPW and the drain region N2B.

In some embodiments, the sub-portions SB1 and SB2 of the drain region N2B have the second conductivity type. For example, when the first conductivity type is P-type, the second conductivity type is N-type, and the sub-portions SB1 and SB2 of the drain region N2B are N-type sub-portions SB1 and SB2.

In some embodiments, the doping concentration of the sub-portions SB1 and SB2 of the drain region N2B is greater than the doping concentration of the drift region ND. In some embodiments, the doping concentration of the drift region ND is in a range about 3*10¹²/cm² to about 6*10¹²/cm², and the doping concentration of the drain region N2B is in a range from 10¹⁴/cm² to about 10¹⁵/cm².

In some embodiments, the sub-portions SB1 and SB2 of the drain region N2B may have different doping concentrations according to the design of device electrical performances (e.g., breakdown voltage). For example, the doping concentrations of sub-portions SB1 and SB2 may decrease gradually toward to the first deep well region DPW.

In some embodiments, the doping concentration of at least one of the sub-portions SB1 and SB2 of the drain region N2B is greater than or equal to the doping concentration of the source region N1.

In the semiconductor structure 500B, the sub-portions SB1 and SB2 of the drain region N2B having the second conductivity type may extend down to the first deep well region DPW having the first conductivity type to form a PN junction. In addition, the sub-portions SB1 and SB2 of the drain region N2B have a higher doping concentration than drift region ND having the second conductivity type. The PN junction between the sub-portions SB1 and SB2 of the drain region N2B and the first deep well region DPW may have a lower breakdown voltage than the PN junction between the drift region ND and the first deep well region DPW. When the semiconductor structure 500B is operated at a high voltage, the PN junction between the sub-portions SB1 and SB2 of the drain region N2B and the first deep well region DPW is more susceptible to breakdown to form a current path (breakdown path) PH2 through the sub-portions SB1 and SB2 of the drain region N2B and the first deep well region DPW, and to the guard ring GR1 to discharge high current away from the gate dielectric layer 252 (and the PN junction between the drift region ND and the first deep well region DPW). Therefore, the gate structure 250 of the transistor in the central active region AC is protected by the design of the sub-portions SB1 and SB2 of the drain region N2B. The gate dielectric layer 252 of the transistor in the central active region AC can be prevented form damage when the semiconductor structure 500B is operated at a high voltage.

In some embodiments, the semiconductor structures 500 may be applicable as switching devices of a buck converter.

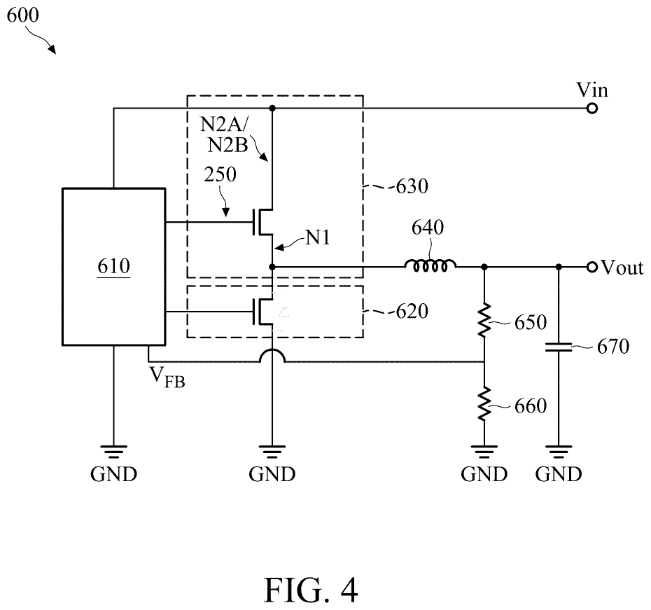

FIG. 4 is a circuit diagram of a buck converter 600 including the semiconductor structures 500A and 500B of FIGS. 1, 2 and 3 in accordance with some embodiments of the present disclosure. In some embodiments, the buck converter 600 includes a buck controller 610, a low voltage side (LS) device 620, a high voltage side (HS) device 630, an inductor 640, resistors 650 and 660, and capacitor 670. In some embodiments, the buck controller 610, the low voltage side (LS) device 620, the high voltage side (HS) device 630, the inductor 640, resistors 650 and 660, and the capacitor 670 are integrated on a single integrated circuit semiconductor substrate, for example, the substrate 200 shown in FIGS. 2 and 3.

The buck controller 610 is connected (coupled) between an input terminal Vin and a ground terminal GND. The low voltage side (LS) device 620 and the high voltage side (HS) device 630 are connected (coupled) to the buck controller 610. The low voltage side (LS) device 620 and the high voltage side (HS) device 630 are connected in series. In addition, the low voltage side (LS) device 620 and the high voltage side (HS) device 630 are connected (coupled) between the input terminal Vin and the ground terminal GND.

In some embodiments, the high voltage side (HS) device 630 is composed of the transistor of the semiconductor structure 500 (including the semiconductor structures 500A and 500B). The transistor of the semiconductor structure 500 includes the gate structure 250, the drain region N2A (or the drain region N2B) and the source region N1.

In some embodiments, the drain region N2A (or the drain region N2B) of the high voltage (HS) device 630 is connected (coupled) to the input terminal Vin. The gate structure 250 of the high voltage (HS) device 630 is connected (coupled) to the buck controller 610. The source region N1 of the high voltage (HS) device 630 is connected (coupled) to the low voltage (LS) device 620 and the inductor 640.

The inductor 640 is connected (coupled) to an output terminal Vout and through the capacitor 670 to the ground terminal GND. In addition, the inductor 640 is connected (coupled) to the ground terminal GND through the resistors 650 and 660 (also called feedback resistors 650 and 660) connected in series. In addition, the resistor 650 is connected (coupled) between the output terminal Vout and a feedback terminal VFB of the buck controller 610. The resistor 660 is connected (coupled) between the feedback terminal VFB of the buck controller 610 and the ground terminal GND.

When a high input voltage is applied at the input terminal Vin, the PN junction between the drain region N2A (or the sub-portions SB1 and SB2 of the drain region N2B) and the first deep well region DPW is more susceptible to breakdown to form the current path PH1 of FIG. 2 (or the current path PH2 of FIG. 3) through the drain region N2A (or the sub-portions SB1 and SB2 of the drain region N2B) and the first deep well region DPW, and to the guard ring GR1 to discharge high current away from the gate dielectric layer 252. Therefore, the gate structure 250 of the high voltage (HS) device 630 is protected by the design of the drain region N2A (or the sub-portions SB1 and SB2 of the drain region N2B). The gate dielectric layer 252 of the high voltage (HS) device 630 can be prevented form damage when the high voltage (HS) device 630 is received a high voltage from the input terminal Vin.

In some embodiments, the low voltage (LS) device 620 is also composed of the transistor of the semiconductor structure 500 (including the semiconductor structures 500A and 500B). The transistor of the semiconductor structure 500 includes the gate structure 250, the drain region N2A (or the drain region N2B) and the source region N1.

In some embodiments, the drain region N2A (or the drain region N2B) of the low voltage (LS) device 620 is connected (coupled) to the source region N1 of the high voltage (HS) device 630. The gate structure 250 of the low voltage (LS) device 620 is connected (coupled) to the buck controller 610. The source region N1 of the low voltage (LS) device 620 is connected (coupled) to the ground terminal GND.

When low voltage (LS) device 620 is operated at a high voltage, the PN junction between the drain region N2A (or the sub-portions SB1 and SB2 of the drain region N2B) and the first deep well region DPW is more susceptible to breakdown to form the current path PHI of FIG. 2 (or the current path PH2 of FIG. 3) through the drain region N2A (or the sub-portions SB1 and SB2 of the drain region N2B) and the first deep well region DPW, and to the guard ring GR1 to discharge high current away from the gate dielectric layer 252. Therefore, the gate structure 250 of the low voltage (LS) device 620 is protected by the design of the drain region N2A (or the sub-portions SB1 and SB2 of the drain region N2B). The gate dielectric layer 252 of the low voltage (LS) device 620 can be prevented form damage when the low voltage (LS) device 620 is operated at a high voltage.

Embodiments of the disclosure provide a semiconductor structure (e.g., a LDMOS transistor). The semiconductor structure includes a substrate, a body region, a drift region, a first deep well region, a gate structure, a source region and a drain region. The body region is located in the substrate. The body region has a first conductivity type. The drift region is located in the substrate and adjacent to the body region. The drift region has a second conductivity type that is different from the first conductivity type. The first deep well region is located in the substrate and below the body region and the drift region. The first deep well region has the first conductivity type. The gate structure is located on the drift region and adjacent to the body region. The source region is located on the body region. The source region has the second conductivity type. The drain region is located adjacent to the drift region in contact with the first deep well region. The drain region has the second conductivity type. Through optimizing the implant and layout of the drain region (e.g., the drain region N2), the drift region (e.g., the drift region ND), and the first deep well region (e.g., the first deep well region DPW) can effectively control the breakdown path through a vertical PN junction (from (e.g., the drain region N2) to the first deep well region (e.g., the first deep well region DPW)), thus preventing damage to the semiconductor structure (e.g., the semiconductor structures 500A and 500B).

In some embodiments, the drift region, the body region and the drain region are in contact with different portions of the first deep well region.

In some embodiments, a first interface between the drain region and the first deep well region is level with a second interface between the drift region and the first deep well region.

In some embodiments, a first interface between the drain region and the first deep well region is level with a third interface between the body region and the first deep well region.

In some embodiments, the drain region includes sub-portions arranged side by side in a direction that is vertical to a top surface of the substrate. The sub-portions have different doping concentrations.

In some embodiments, the doping concentrations of the sub-portions decrease gradually toward to the first deep well region.

In some embodiments, the semiconductor structure further includes a first isolation feature surrounding the drift region, the body region and the drain region. A bottom of the first isolation feature is located below the second interface between the drift region and the first deep well region.

In some embodiments, a side surface of the first isolation feature is adjacent to the first deep well region and the drain region.

In some embodiments, a first depth of the drain region is greater than a second depth of the source region.

In some embodiments, the semiconductor structure further includes a first guard ring and a second guard. The first guard is located in the substrate and surrounding the first deep well region, the drift region, the body region and the drain region. The first guard ring includes a first well region and a first pick-up region. The first well region has the first conductivity type. The first pick-up region is located on the first well region. The first pick-up region has the first conductivity type. The second guard ring is located in the semiconductor substrate and surrounding the first guard ring. The second guard ring includes a second well region and a second pick-up region. The second well region has the second conductivity type. The second pick-up region is located on the second well region, wherein the second pick-up region has the second conductivity type.

In some embodiments, the first pick-up region is separated from the drain region by the first isolation feature.

In some embodiments, the semiconductor structure further includes a second isolation feature, a second deep well region, and a first intrinsic doped region. The second isolation feature surrounds the first guard ring. The first pick-up region is separated from the second pick-up region by the second isolation feature. The second deep well region is located in the substrate and below the first deep well region, the first guard ring and the second guard ring. The second deep well region has the second conductivity type. The first intrinsic doped region is surrounded by the first guard ring, the second guard ring, the second isolation feature and the second deep well region. The first intrinsic doped region and the substrate have the same conductivity type and doping concentration.

In some embodiments, the semiconductor structure further includes a third guard ring and a third isolation feature. The third guard ring is located in the substrate and surrounding the second guard ring. The third guard ring includes a third well region and a third pick-up region. The third well region is separated from the second well region and has the first conductivity type. The third pick-up region is located on the third well region. The third pick-up region has the first conductivity type. The third isolation feature surrounds the second guard ring. The second pick-up region is separated from the third pick-up region by the third isolation feature.

Embodiments of the disclosure provide a bulk convertor. The bulk convertor includes a buck controller, a low voltage (LS) device, and a high voltage (HS) device. The low voltage (LS) device is connected to the buck controller. The high voltage (HS) device is connected to the buck controller. The high voltage (HS) device is composed of a first semiconductor structure including a substrate, a body region, a drift region, a first deep well region, a gate structure, a source region and a drain region. The body region is located in the substrate. The body region has a first conductivity type. The drift region is located in the substrate and adjacent to the body region. The drift region has a second conductivity type that is different from the first conductivity type. The first deep well region is located in the substrate and below the body region and the drift region. The first deep well region has the first conductivity type. The gate structure is located on the drift region and adjacent to the body region. The source region is located on the body region. The source region has the second conductivity type. The drain region is located adjacent to the drift region in contact with the first deep well region. The drain region has the second conductivity type.

In some embodiments, the low voltage (LS) device is composed of a second semiconductor structure that is the same as the first semiconductor structure.

In some embodiments, the drain region of the high voltage (HS) device is connected to an input terminal.

In some embodiments, the gate structure of the high voltage (HS) device is connected to the buck controller.

In some embodiments, the source region of the high voltage (HS) device is connected to the low voltage (LS) device and an inductor.

In some embodiments, the inductor is connected to an output terminal (Vout) and through a capacitor to a ground terminal.

In some embodiments, the inductor is connected to the ground terminal through resistors.

In some embodiments, the high voltage (HS) device and the low voltage (LS) device are connected in series between an input terminal and a ground terminal.

In some embodiments, the buck controller is connected between an input terminal and a ground terminal.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

1. A semiconductor structure, comprising:
a substrate;
a body region located in the substrate, wherein the body region has a first conductivity type;
a drift region located in the substrate and adjacent to the body region, wherein the drift region has a second conductivity type that is different from the first conductivity type;
a first deep well region located in the substrate and below the body region and the drift region, wherein the first deep well region has the first conductivity type;
a gate structure located on the drift region and adjacent to the body region;
a source region located on the body region, wherein the source region has the second conductivity type; and
a drain region located adjacent to the drift region in contact with the first deep well region, wherein the drain region has the second conductivity type.

2. The semiconductor structure as claimed in claim 1, wherein the drift region, the body region and the drain region are in contact with different portions of the first deep well region.

3. The semiconductor structure as claimed in claim 2, wherein a first interface between the drain region and the first deep well region is level with a second interface between the drift region and the first deep well region.

4. The semiconductor structure as claimed in claim 2, wherein a first interface between the drain region and the first deep well region is level with a third interface between the body region and the first deep well region.

5. The semiconductor structure as claimed in claim 2, wherein the drain region comprises sub-portions arranged side by side in a direction that is vertical to a top surface of the substrate, and the sub-portions have different doping concentrations.

6. The semiconductor structure as claimed in claim 5, wherein the doping concentrations of the sub-portions decrease gradually toward to the first deep well region.

7. The semiconductor structure as claimed in claim 2, further comprising:
a first isolation feature surrounding the drift region, the body region and the drain region, wherein a bottom of the first isolation feature is located below the second interface between the drift region and the first deep well region.

8. The semiconductor structure as claimed in claim 7, wherein a side surface of the first isolation feature is adjacent to the first deep well region and the drain region.

9. The semiconductor structure as claimed in claim 1, wherein a first depth of the drain region is greater than a second depth of the source region.

10. The semiconductor structure as claimed in claim 7, further comprising:
a first guard ring located in the substrate and surrounding the first deep well region, the drift region, the body region and the drain region, wherein the first guard ring comprises:
a first well region, wherein the first well region has the first conductivity type; and
a first pick-up region located on the first well region, wherein the first pick-up region has the first conductivity type; and
a second guard ring located in the semiconductor substrate and surrounding the first guard ring, wherein the second guard ring comprises:
a second well region, wherein the second well region has the second conductivity type; and
a second pick-up region located on the second well region, wherein the second pick-up region has the second conductivity type.

11. The semiconductor structure as claimed in claim 10, wherein the first pick-up region is separated from the drain region by the first isolation feature.

12. The semiconductor structure as claimed in claim 10, further comprising:
a second isolation feature surrounding the first guard ring, wherein the first pick-up region is separated from the second pick-up region by the second isolation feature;
a second deep well region located in the substrate and below the first deep well region, the first guard ring and the second guard ring, wherein the second deep well region has the second conductivity type; and
a first intrinsic doped region surrounded by the first guard ring, the second guard ring, the second isolation feature and the second deep well region, wherein the first intrinsic doped region and the substrate have the same conductivity type and doping concentration.

13. The semiconductor structure as claimed in claim 12, further comprising:
a third guard ring located in the substrate and surrounding the second guard ring, wherein the third guard ring comprises:
a third well region separated from the second well region, wherein the third well region has the first conductivity type; and
a third pick-up region located on the third well region, wherein the third pick-up region has the first conductivity type; and
a third isolation feature surrounding the second guard ring, wherein the second pick-up region is separated from the third pick-up region by the third isolation feature.

14. A buck convertor, comprising:
a buck controller;
a low voltage (LS) device connected to the buck controller; and
a high voltage (HS) device connected to the buck controller, wherein the high voltage (HS) device is composed of a first semiconductor structure comprising:
a substrate;
a body region located in the substrate, wherein the body region has a first conductivity type;
a drift region located in the substrate and adjacent to the body region, wherein the drift region has a second conductivity type that is different from the first conductivity type;
a first deep well region located in the substrate and below the body region and the drift region, wherein the first deep well region has the first conductivity type;
a gate structure located on the drift region and adjacent to the body region;
a source region located on the body region, wherein the source region has the second conductivity type; and
a drain region located adjacent to the drift region in contact with the first deep well region, wherein the drain region has the second conductivity type.

15. The buck convertor as claimed in claim 14, wherein the low voltage device is composed of a second semiconductor structure that is the same as the first semiconductor structure.

16. The buck convertor as claimed in claim 14, wherein the drain region of the high voltage (HS) device is connected to an input terminal, the gate structure of the high voltage (HS) device is connected to the buck controller, and the source region of the high voltage (HS) device is connected to the low voltage (LS) device and an inductor.

17. The buck convertor as claimed in claim 16, wherein the inductor is connected to an output terminal and through a capacitor to a ground terminal.

18. The buck convertor as claimed in claim 16, wherein the inductor is connected to the ground terminal through resistors.

19. The buck convertor as claimed in claim 12, wherein the high voltage (HS) device and the low voltage (LS) device are connected in series between an input terminal and a ground terminal.

20. The buck convertor as claimed in claim 12, wherein the buck controller is connected between an input terminal and a ground terminal.
